(19) United States
(12) Patent Application Publication
(10) Pub. No.: US 2005/0127496 A1
(43) Pub. Date: Jun. 16, 2005

(54) Bonding pads with dummy patterns in semiconductor devices and methods of forming the same

(76) Inventors: Ki-hyoun Kwon, Gyeonggi-do (KR); Kyung-tae Lee, Seoul (KR); Seong-ho Liu, Gyeonggi-do (KR); Yoon-hae Kim, Gyeonggi-do (KR)

Correspondence Address: MYERS BIGEL SIBLEY & SAJOVEC, PO BOX 37428, RALEIGH, NC, 27627, US

(21) Appl. No.: 10/978,619

(22) Filed: Nov. 1, 2004

(30) Foreign Application Priority Data
Nov. 1, 2003 (KR) 10-2003-0077189

(51) Int. Cl. H01L 23/12; H01L 21/4763

(52) U.S. Cl. 257/700; 257/758; 438/622

(57) ABSTRACT

A bonding pad in a semiconductor device can include a conductive plug pattern on a conductive layer, where the conductive layer includes a conductive material and a dummy pattern surrounded by the conductive material. Related methods are also disclosed.

### CROSS-REFERENCE TO RELATED APPLICATION

This application claims the priority of Korean Patent Application No. 2003-77189, filed on Nov. 1, 2003, in the Korean Intellectual Property Office, the disclosure of which is incorporated herein in its entirety.

### FIELD OF THE INVENTION

The present invention relates to bonding pads in semiconductor devices and methods of manufacturing the same.

### BACKGROUND

As the area of a wafer used in the manufacture of a semiconductor device increases, a technique that performs polishing over a wide area becomes increasingly important. Thus, there has been a growing interest in chemical mechanical polishing (CMP) that performs planarization for a wide area.

Although CMP is a process suitable for polishing a wide area, since a wide area and a narrow area of a surface of an object to be polished are polished at different rates, the step height difference between the wide area and narrow areas increases. Thus, the surface to be polished is recessed like a dish, which is known as a dishing effect. As shown in FIG. 1, the dishing effect decreases as the density of a pattern contained in the object increases.

As the integration density of a semiconductor device increases, CMP may be more widely used in various steps in a semiconductor manufacturing process. For example, CMP may be used in the step of forming a bonding pad requiring an area larger than those of other portions of the semiconductor device.

FIG. 2 shows a plan view of a conventional bonding pad. Reference numeral 10 in FIG. 2 denotes a wire-bonded metallization layer. The metallization layer 10 is composed of multiple metal layers 10a-10d sequentially stacked as shown in FIG. 3. Reference numerals 13 and 12 denote a plurality of via holes formed in an interlevel dielectric layer between the multiple metal layers 10a-10d contained in the metallization layer 10 and a conductive plug that fills each via hole 13.

Referring to FIG. 3, the interlevel dielectric layers 14 and 16 are sandwiched between the metal layers 10a and 10b and between the metal layers 10c and 10d, respectively. A plurality of via holes 13a and 13b are formed in the interlevel dielectric layers 14 and 16, respectively, and subsequently filled with conductive plugs 18 and 20, respectively.

The conventional bonding pad uses copper (Cu) which may have a lower electrical specific resistance and increased mobility relative to aluminum (Al) as conductive plugs 18 and 20 to reduce RC delay. For the interlevel dielectric layers 14 and 16, a low-dielectric constant (k) material is used instead of a silicon oxide layer to reduce parasitic capacitance.

Since it may be difficult to etch Cu, the conductive plugs 18 and 20 made of Cu are typically formed by a damascene process. More specifically, a process of forming a conductive plug 18 involves forming a copper layer on the interlevel dielectric layer 14 to fill the via hole 13a and polishing the entire surface of the copper layer by CMP to expose the interlevel dielectric layer 14. The CMP process continues until a conductive plug 20 is formed to contact the uppermost metal layer 10d.

Since a dishing effect may occur each time CMP is performed, a final dishing effect after formation of the conductive plug 20 contains accumulated dishing effects caused by preceding CMPs. Thus, the conventional bonding pad suffers from a severe dishing effect that cannot be ignored during the formation. This may cause damage to patterns formed around the bonding pad during the formation of the bonding pad and degrades resistance characteristics of the bonding pad.

Another drawback is that using an interlevel dielectric layer made of a low-k material in order to reduce the parasitic capacitance may weaken mechanical bonds between metal layers contained in the bonding pad. That is, when the interlevel dielectric layer is made of a low-k material, mechanical strength of the bonding pad may be decreased so the bonding pad is damaged or ripped from a chip during bonding.

FIG. 4 is a photograph showing that the bonding pad is ripped from a chip during a bonding process. Reference numerals 20, 22, and 24 denote a wire used for bonding, a bonding pad, and an underlying layer revealed through the ripped portion of the bonding pad, respectively.

### SUMMARY

Embodiments according to the invention can provide bonding pads with dummy patterns in semiconductor devices and methods of forming the same. Pursuant to these embodiments, a bonding pad in a semiconductor device can include a conductive plug pattern on a conductive layer, where the conductive layer includes a conductive material and a dummy pattern surrounded by the conductive material. In some embodiments according to the invention, the dummy pattern is an insulating material.

In some embodiments according to the invention, the conductive material is a first conductive material the dummy pattern is a second conductive material. In some embodiments according to the invention, the dummy pattern is a polygonal shaped element. In some embodiments according to the invention, the dummy pattern is a cross shaped dummy element, a circular shaped dummy element, a rectangular shaped element, a square shaped element, and/or a triangular shaped element.

In some embodiments according to the invention, the conductive plug pattern is a conductive element having at least one opening therein opposite the dummy pattern. In some embodiments according to the invention, the at least one opening is filled with a dielectric material.

In some embodiments according to the invention, the dummy pattern can be a plurality of dummy elements surrounded by the conductive material, the conductive plug pattern can further include a conductive element including an array of openings therein opposite respective ones of the plurality of dummy elements.

In some embodiments according to the invention, the dummy pattern further includes a plurality of dummy elements surrounded by the conductive material, and the conductive plug pattern can further include a plurality of conductive elements each having an opening therein opposite a respective one of the plurality of dummy elements. In some embodiments according to the invention, the plurality of conductive elements are connected via conductive interconnects.

In some embodiments according to the invention, the dummy pattern can further include a plurality of dummy elements surrounded by the conductive material, and the conductive plug pattern can further include a plurality of conductive elements each having an opening therein offset from respective ones of the plurality of dummy elements. In some embodiments according to the invention, the plurality of conductive elements are connected via conductive interconnects.

In some embodiments according to the invention, the conductive plug pattern is a first conductive plug pattern, and the conductive layer is a first conductive layer including a first conductive material and an embedded first dummy pattern surrounded by the first conductive material. The bonding pad can further include a second conductive layer on the first conductive plug pattern opposite the first conductive layer, and the second conductive layer can include a second conductive material and an embedded second dummy pattern opposite openings in the first conductive plug pattern and surrounded by the second conductive material.

In some embodiments according to the invention, the bonding pad can further include a second conductive plug pattern on the second conductive layer opposite the first conductive plug pattern. The second conductive plug pattern can include openings therein opposite the embedded second dummy pattern.

In some embodiments according to the invention, methods of forming a bonding pad in a semiconductor device include forming a conductive plug pattern on a conductive layer, where the conductive layer includes a conductive material and a dummy pattern surrounded by the conductive material. In some embodiments according to the invention, forming the conductive plug pattern includes forming the conductive element having at least one opening therein opposite the dummy pattern.

In some embodiments according to the invention, methods of forming a bonding pad in a semiconductor device can include forming a dummy pattern on an underlying layer and forming a conductive material on the dummy pattern. A portion of the conductive material can be removed to expose the dummy pattern to form a conductive layer with the dummy pattern embedded therein. An interlevel dielectric layer is formed on the conductive layer to expose a portion of the conductive material therethrough opposite the dummy pattern. A conductive plug is formed on the exposed portion of the conductive material to avoid forming the conductive plug on the interlevel dielectric layer opposite the dummy pattern.

### BRIEF DESCRIPTION OF THE DRAWINGS

FIG. 1 is a graph illustrating relationship of dishing effect versus pattern density;

FIG. 2 is a plan view of a conventional bonding pad.

FIG. 3 is a cross-sectional view taken along line 3-3′ of FIG. 2.

FIG. 4 is a plan view illustrating damage to a conventional bonding pad.

FIGS. 5-7 are perspective views of bonding pads according to some embodiments of the present invention.

FIG. 8 is a plan view of a resulting structure in which the first conductive plug having a first pattern has been formed on the first metal layer in the bonding pad of FIG. 5 where the first dummy pattern having a first shape is distributed according to some embodiments of the present invention.

FIG. 9 is a plan view of a resulting structure in which the second metal layer with a second dummy pattern having the first shape and which contacts the first conductive plug having the first pattern has been formed on the resulting structure of FIG. 8 according to some embodiments of the present invention.

FIG. 10 is a plan view of a resulting structure in which the first dummy pattern having the first shape of FIG. 8 has been replaced with the first dummy pattern having a second shape according to some embodiments of the present invention.

FIG. 11 is a plan view of a resulting structure in which the first metal layer and the first conductive plug in an embodiment of the present invention has been replaced with the first metal layer where the first dummy pattern having a third shape is distributed and the first conductive plug having a fourth pattern, respectively according to some embodiments of the present invention.

FIG. 12 is a plan view of a resulting structure in which the first dummy pattern having the first shape distributed over the first metal layer of FIG. 9 has been replaced with the first dummy pattern having the second shape according to some embodiments of the present invention.

FIG. 13 is a plan view of a resulting structure in which the first conductive plug having a second pattern has been formed on the first metal layer of the bonding pad of FIG. 6 where the first dummy pattern having the first shape is distributed according to some embodiments of the present invention.

FIG. 14 is a plan view of a resulting structure in which the first conductive plug having a third pattern has been formed on the first metal layer of the bonding pad of FIG. 7 where the first dummy pattern having the first shape is distributed according to some embodiments of the present invention.

FIG. 15 is a perspective view of a bonding pad that is a combination of some the aspects illustrated in FIGS. 5-15 according to some embodiments of the present invention.

FIG. 16 is a cross-sectional view taken along line 16-16′ of FIG. 9.

FIG. 17 is a cross-sectional view taken along line 17-17′ of FIG. 13.

FIG. 18 is a cross-sectional view showing a state in which the subsequently formed conductive plugs are located at different positions than the previously formed conductive plug in the bonding pad shown in FIG. 16 according to some embodiments of the present invention.

FIG. 19 is a cross-sectional view showing a state in which the subsequently formed conductive plugs are located at different positions than the previously formed conductive plugs in the bonding pad shown in FIG. 17 according to some embodiments of the present invention.

FIGS. 20-28 are cross-sectional views showing methods of forming a bonding pad of FIG. 5 according to some embodiments of the present invention.

FIG. 29 is a cross-sectional view showing methods of forming the bonding pad shown in FIG. 18 according to some embodiments of the present invention.

FIGS. 30-34 are cross-sectional views showing methods of forming the bonding pad of FIG. 5 according to some embodiments of the present invention.

FIGS. 35 and 36 are graphs showing dishing effects measured on a conventional bonding pad and a bonding pad according to embodiments of the present invention.

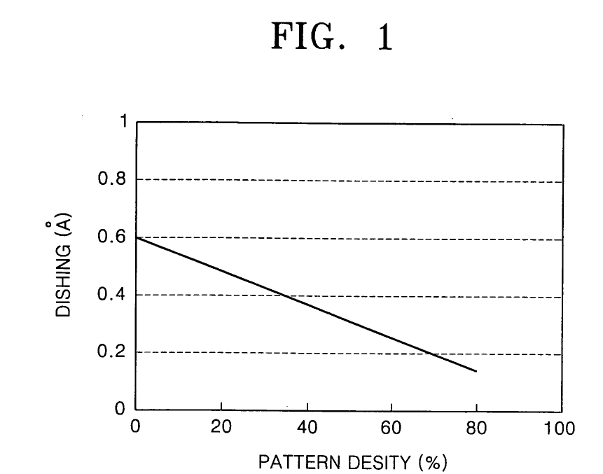

### DESCRIPTION OF EMBODIMENTS ACCORDING TO THE INVENTION

The invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. As used herein the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element such as a layer, film, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers refer to like elements throughout the specification.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, film, layer or section. Thus, a first element, component, region, layer or section discussed below could be termed a second element, component, region, layer or section without departing from the teachings of the present invention.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below. It will be understood that the terms “film” and “layer” mat be used interchangeably herein.

Embodiments of the present invention are described herein with reference to cross-section (and/or plan view) illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated or described as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will also be appreciated by those of skill in the art that references to a structure or feature that is disposed “adjacent” another feature may have portions that overlap or underlie the adjacent feature.

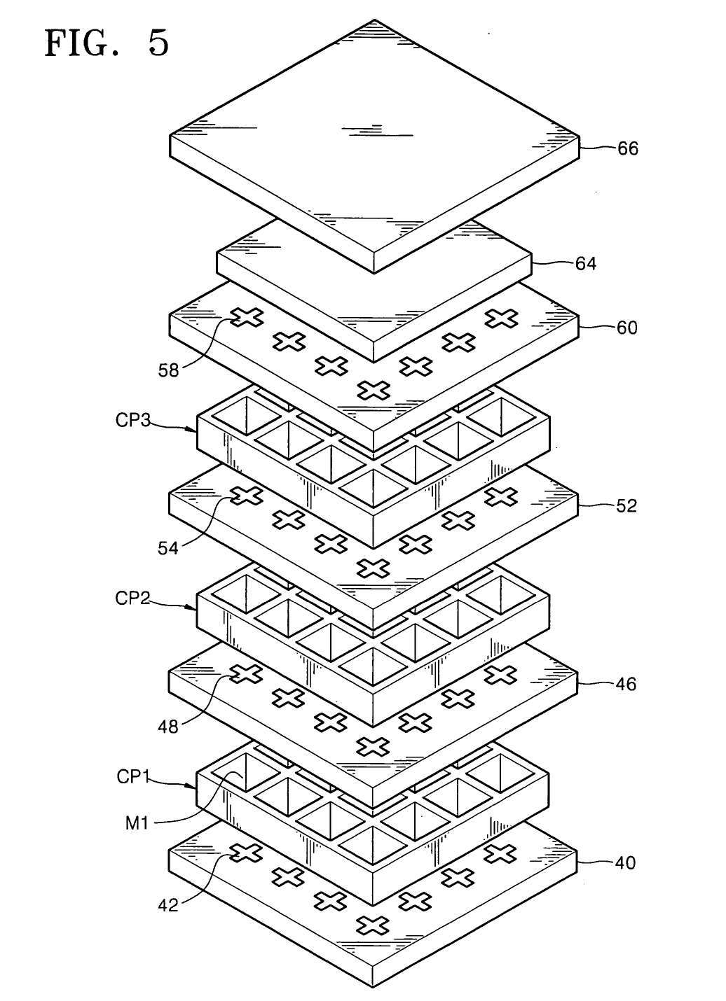

As discussed herein in greater detail, in some embodiments according to the invention, a conductive plug pattern can be formed on a conductive layer wherein the conductive layer includes a conductive material and an embedded dummy pattern that is surrounded by the conductive material. For example, as shown for example in FIG. 5, the conductive plug pattern CP1 is on a conductive layer (such as a metal layer) 40 that is formed of a conductive material and includes an embedded dummy pattern 42 that is surrounded by the conductive material.

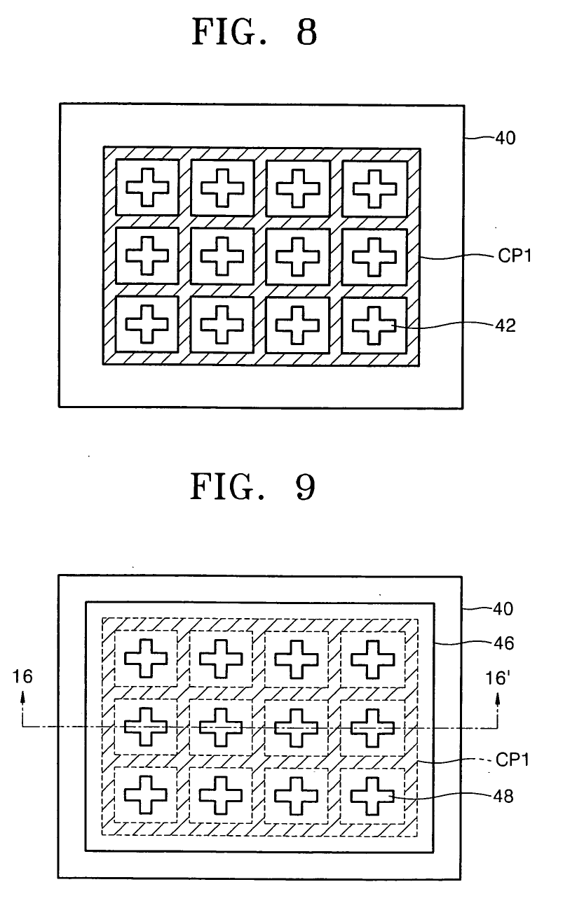

As further illustrated by FIGS. 5 and 8, the dummy pattern 42 can be placed in the conductive layer 40 aligned to openings in the conductive plug CP1. It will be understood that the openings through which the dummy pattern is otherwise exposed can be filled with a dielectric material. In still further embodiments according to the invention, the embedded dummy patterns can be any polygonal shaped element such as cross shaped dummy element, circular shaped dummy element, n rectangular shaped dummy element, a square shaped dummy element and/or a triangular shaped dummy element.

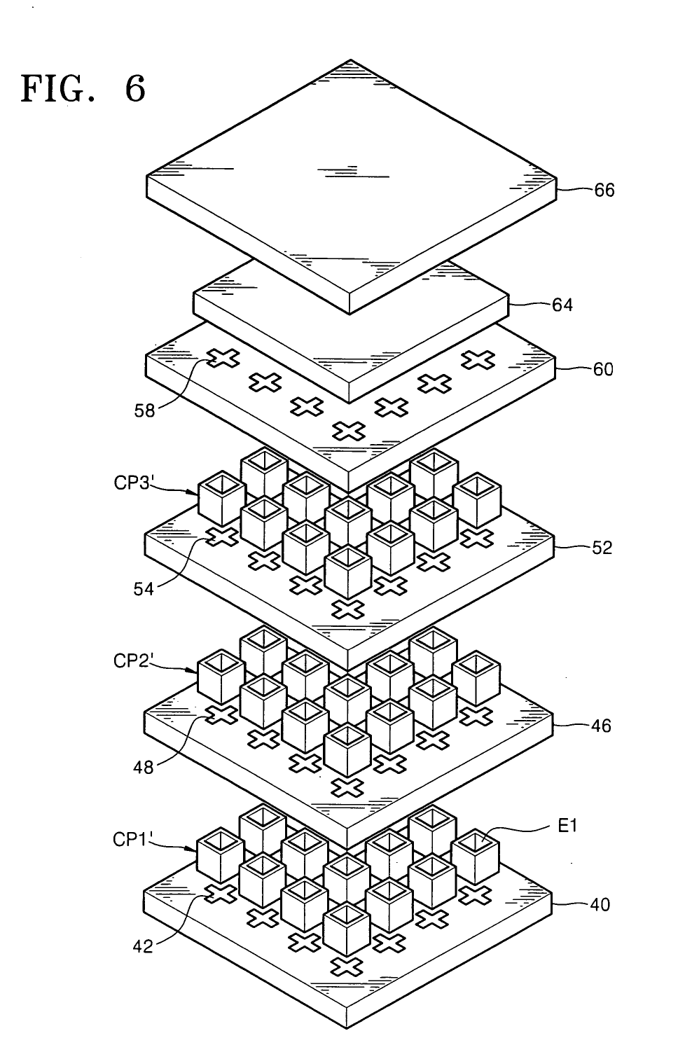

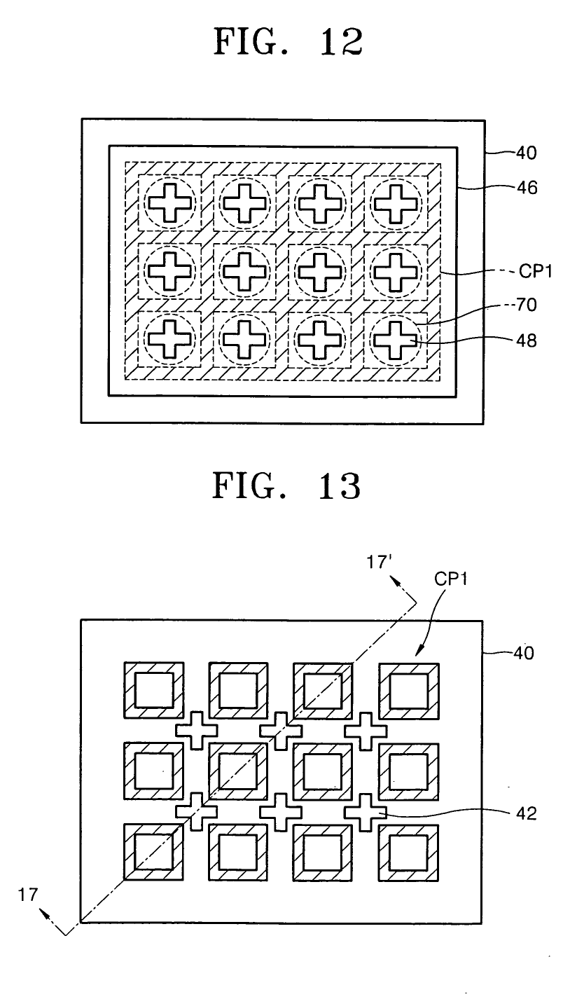

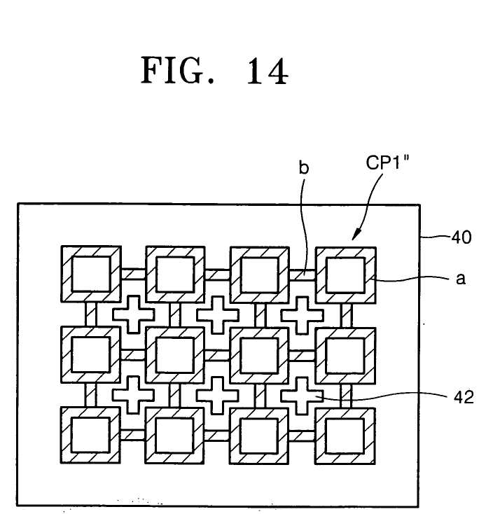

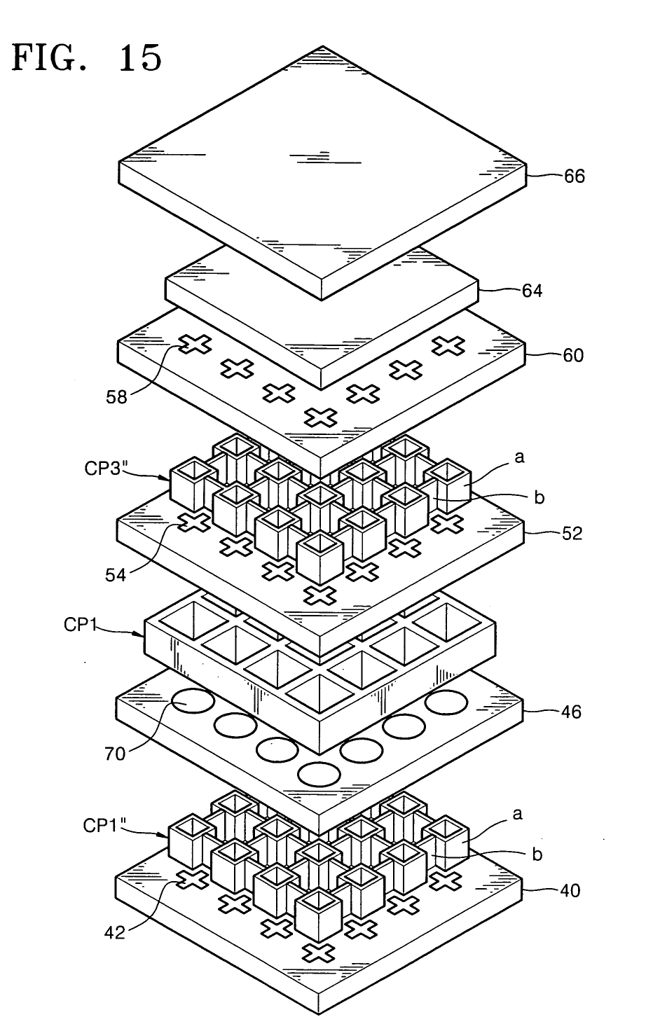

Yet further embodiments according to the invention, as illustrated for example in FIG. 6, the conductive plug pattern can include a plurality of conductive elements each having an opening therein opposite a respective one of a plurality of dummy element 42. In still further embodiments according to the invention as shown for example in FIGS. 14 and 15, the conductive elements included in the conductive plug can be interconnected with one another via conductive interconnects “b”. It will be further understood that bonding pads according to the embodiments of the invention can include multiple conductive layers each having respective dummy patterns embedded therein, and further, can be integrated with respective conductive plugs that can be formed as unitary structures with the underlined conductive layer on which it is formed. Yet further embodiments according to the invention, the dummy patterns in the conductive layers can be offset (i.e. unaligned) with the openings in the overlying conductive plugs. For example, in some embodiments according to the invention as shown for example in FIG. 14, the dummy patterns 42 are located between conductive elements included in the conductive plug. It will be understood that in some embodiments according to the invention where the dummy patterns are offset from the conductive elements, the conductive elements may or may not be interconnected via conductive interconnects as discussed above. It will be further understood that the conductive layers discussed herein may be other materials suitable for use in bonding pads. The dummy patterns disclosed herein can include a single dummy element or a plurality of dummy elements.

Referring to FIG. 5, a bonding pad according to some embodiments of the present invention (hereinafter referred to as a first bonding pad) includes first through sixth metal layers 40, 46, 52, 60, 64, and 66. The metal layers may be conductive layers. First through third conductive plugs CP1-CP3 are formed between the first and second metal layers 40 and 46, between the second and third metal layers 46 and 52, and the third and fourth metal layers 52 and 60, respectively. Each metal layer may be a copper layer formed by a damascene process. While an interlevel dielectric layer is formed between the first through sixth metal layers 40, 46, 52, 60, 64, and 66, they are not shown in FIGS. 5-7 for better visualization. Furthermore, one of the first through third conductive plugs CP1-CP3, e.g., a portion of the second conductive plug CP2 may be replaced with a wide pad layer.

Referring to FIG. 5, a first dummy pattern 42 is distributed in the first metal layer 40 and may be an insulating pillar. The first dummy pattern 42 is embedded into the first metal layer 40 to form a flat surface with the first dummy pattern 42. The first dummy pattern 42 can be distributed uniformly in the first metal layer 40 in order to increase the pattern density of the first metal layer 40 and thus reduce dishing effect caused by chemical mechanical polishing (CMP).

Each sub-pattern of the first dummy pattern 42 may have a cross shape (hereinafter referred to as a first shape). It will be understood that the dummy pattern shape is not limited to any specific one. For example, the first dummy pattern 42 may have other various shapes such as circle and slit besides the first shape. Second through fourth dummy patterns 48, 54, and 58 are formed in the second through fourth metal layers 46, 52 and 60, respectively. The second through fourth dummy patterns 48, 54, and 58 perform the same function as the first dummy pattern 42 and are perforated (embedded) into the second through fourth metal layers 46, 52, and 60, respectively.

The second through fourth dummy patterns 48, 54, and 58 may all have the first shape or other shapes. The fifth metal layer 64 is an intermediate metal layer connecting the first through fourth metal layers 40, 46, 52, and 60 with the uppermost metal layer 66 and contacts the entire surface of the fourth dummy pattern 58 distributed uniformly in the fourth metal layer 60 as well as the fourth metal layer 60 around the fourth dummy pattern 58. The fifth metal layer 64 may contact the entire surface of the fourth dummy pattern 58 and the fourth metal layer 60. The sixth metal layer 66 comes in direct contact with a wire used for bonding. The first through sixth metal layers 40, 46, 52, 60, 64, and 66 may be copper layers or other metal layers with properties comparable to (or better than) the copper layer.

Each of the first through fourth conductive plugs CP1-CP4 is a mesh made of the same material as the first through sixth metal layers 40, 46, 52, 60, 64, and 66. The meshes of each of the conductive plugs CP1-CP4 correspond one-to-one to individual sub-patterns of each of the underlying dummy patterns 42, 48, 54, and 58. For example, a unit mesh M1 of the first conductive plug CP1 corresponds to one individual sub-pattern of the underlying first dummy pattern 42. As is evident in FIGS. 5 and 8, a corresponding sub-pattern of the first dummy pattern 42 distributed in the first metal layer 40 is located at the center of the unit mesh M1 of the first conductive plug CP1.

While FIG. 5 shows the first through third conductive plugs CP1-CP3 are separated from the second through fourth metal layers 46, 52, and 60, respectively, the first through third conductive plugs CP1-CP3 may be integrated with corresponding metal layers 46, 52, and 50, respectively (i.e., formed as a unitary structure).

Referring to FIG. 6, a bonding pad according to some embodiments of the present invention (hereinafter referred to as a second bonding pad) includes fourth through sixth conductive plugs CP1′-CP3′ formed between first and second metal layers 40 and 46, between second and third metal layers 46 and 52, and between third and fourth metal layers 52 and 60, respectively. The fourth conductive plug CP1′ is includes a plurality of individual plug elements E1, each having a rectangular shape including an opening therethrough (referred to hereinafter as a “doughnut shape”). The plurality of individual plug elements E1 are arranged in a predetermined pattern, e.g., a grid array. In this case, each plug element E1 is surrounded by four sub-patterns of the first dummy pattern 42 having the first shape. Each sub-pattern of the first dummy pattern 42 having the first shape is surrounded by (i.e., is offset from) four plug elements E1. Thus, each plug element E1 corresponds to four sub-patterns of the first dummy pattern 42 while each sub-pattern of the first dummy pattern 42 corresponds to four plug elements E1.

The relationship between a position in the fourth conductive plug CP1′ and the first dummy pattern 42 is evident in FIG. 13 that shows a planar shape of the fourth conductive plug CP1′. The fifth and/or sixth conductive plugs CP2′ and CP3′ includes of a plurality of plug elements and arranged in the same pattern as the fourth conductive plug CP1′.

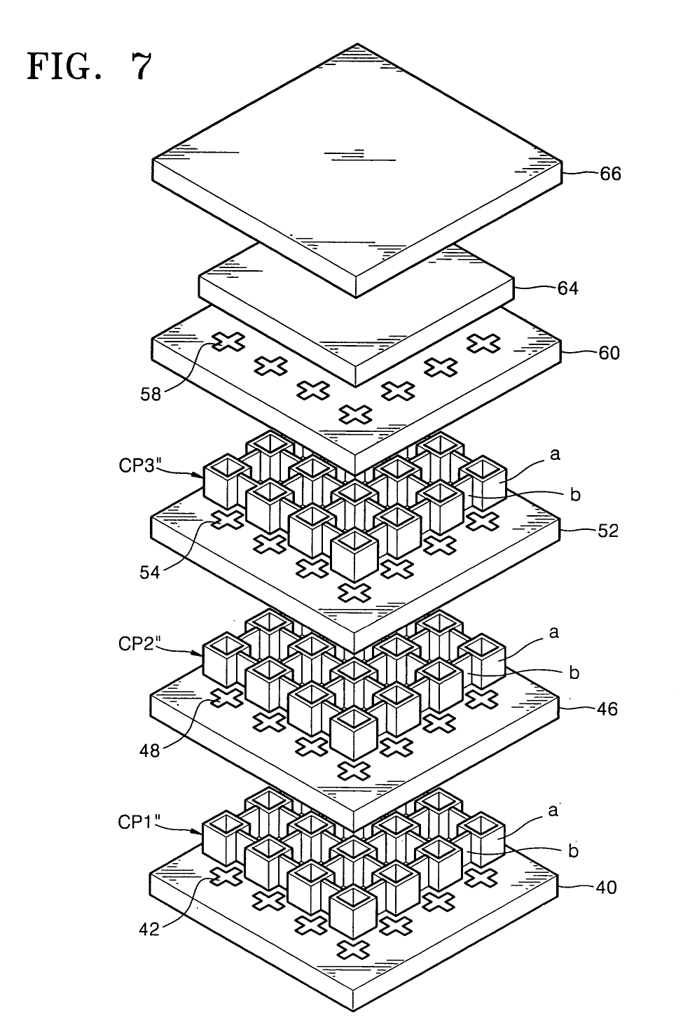

Referring to FIG. 7, a bonding pad according to some embodiments of the invention (hereinafter referred to as a third bonding pad) includes seventh through ninth conductive plugs CP1″-CP3″ formed between first and second metal layers 40 and 46, between second and third metal layers 46 and 52, and between third and fourth metal layers 52 and 60, respectively. The seventh through ninth conductive plugs CP1″-CP3″ may have the same or different patterns. As is evident by FIG. 14 showing a planar shape of the seventh conductive plug CP1″, each of the seventh through ninth conductive plugs CP1″-CP3″ is designed as a combination of the mesh-shaped and rectangular doughnut-shaped conductive plugs as disclosed herein.

More specifically, referring to FIGS. 7 and 14, the seventh conductive plug CP1″ includes a plurality of rectangular elements (i.e., conductive interconnects) a and lines b connecting them with each other. Each sub-pattern of the first dummy pattern 42 having the first shape distributed over the first metal layer 40 underlying the seventh conductive plug CP1″ is surrounded by four rectangular elements a connected to each other by the lines b. The same can apply to the eight and/or ninth conductive plugs CP2″ and/or CP3″.

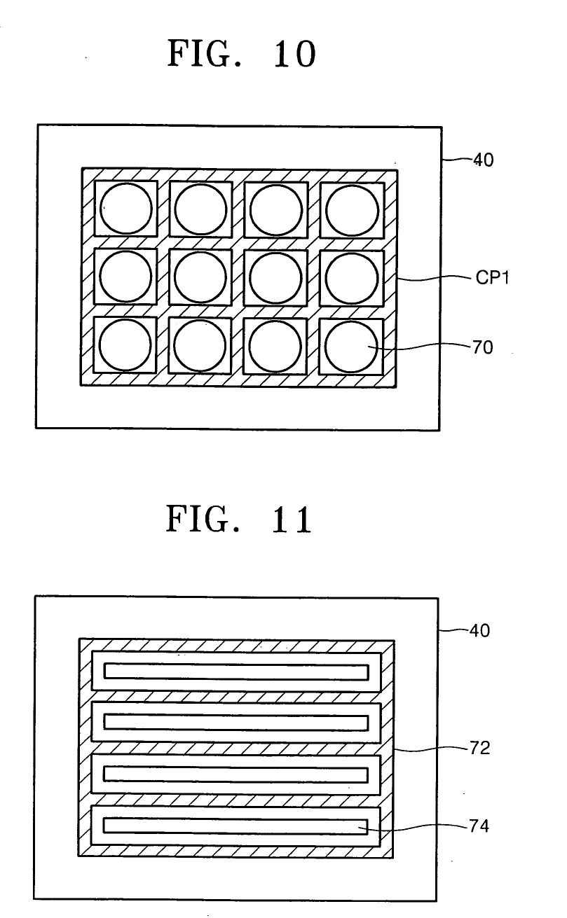

FIG. 8 is a plan view of a resulting structure in which the first conductive plug CP1 has been formed on the first metal layer 40 of the first bonding pad, and FIG. 9 is a plan view of a resulting structure in which the second metal layer 46 with the second dummy pattern 48 has been formed on the first conductive plug CP1. While the second metal layer 46 can have the same size as the first metal layer 40, FIG. 9 shows that the former is smaller than the latter for clarity. The same applies to FIG. 12. As shown in FIG. 10, a first dummy pattern 70, each sub-pattern having a circular shape (hereinafter referred to as a second shape), may be embedded in the first metal layer 40.

Furthermore, Referring to FIG. 11, a first dummy pattern 74, each sub-pattern having a slit shape (hereinafter referred to as a third shape), may be distributed in the first metal layer 40 instead of the first dummy pattern 42 having the first shape. A tenth conductive plug 72 may be subsequently formed on the first metal layer 40 in which the first dummy pattern 74 is distributed. Elements of the tenth conductive plug 72 are a plurality of slits connected in parallel, each surrounding each sub-pattern of the first dummy pattern 74 having the third shape. That is, each of the plurality of slits corresponds to each sub-pattern of the first dummy pattern 74.

Meanwhile, the dummy pattern embedded in the first metal layer 40 may be different from that embedded in one of the second through fourth metal layers 46, 52, and 60. FIG. 12 shows an example in which the dummy pattern embedded in the first metal layer 40 is different from that in the second metal layer 46.

More specifically, referring to FIG. 12, while the first dummy pattern 70 having the second shape is distributed over the first metal layer 40, the second dummy pattern 48 having the first shape is distributed over the second metal layer 46. FIG. 13 is a plan view of a resulting structure in which the fourth conductive plug CP1′ has been formed on the first metal layer 40 where the first dummy pattern 42 having the first shape is distributed, and FIG. 14 is a plan view of a resulting structure in which the seventh conductive plug CP1″ has been formed on the first metal layer 40.

Based on the foregoing, since the dummy patterns embedded in the first through fourth metal layers 40, 46, 52, and 60 and the pattern of the conductive plugs may have different shapes, it is possible to realize other various bonding pads in addition to the first through third bonding pads. FIG. 15 shows another example of a bonding pad according to the present invention. Specifically, referring to FIG. 15, the first dummy patterns 42 having the first shapes are embedded in the first, third, and fourth metal layers 40, 52, and 60, respectively, and the first dummy pattern 70 having the second shape is embedded in the second metal layer 46. Furthermore, the seventh conductive plug CP1″, the first conductive plug CP1, and the ninth conductive plug CP3″ are sandwiched between the first and second metal layers 40 and 46, between the second and third metal layers 46 and 52, and between the third and fourth metal layers 52 and 60, respectively.

In the first through third bonding pads and the bonding pad of FIG. 15, the fifth metal layer 64 may be replaced with another metal layer where a dummy pattern is distributed such as any one of the first through fourth metal layers 40, 46, 52, and 60. The number of metal layers making up the bonding pad may vary depending on the type of application.

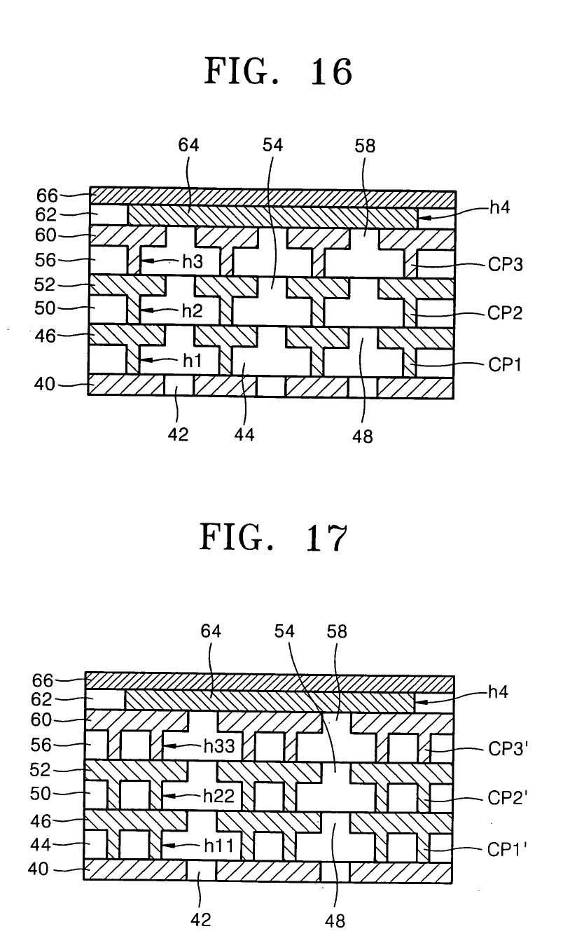

FIG. 16 is a cross-sectional view taken along line 16-16′ of FIG. 9 showing the first bonding pad, assuming that the third through sixth metal layers 52, 60, 64, and 66 and the second and third conductive plugs CP2 and CP3 overlie the second metal layer 46 shown in FIG. 9. FIG. 9 only shows the first and second metal layers 40 and 46 and the first conductive plug CP1 since the overlying elements, i.e., the third and fourth metal layers 52 and 60 and the second and third conductive plugs CP2 and CP3 are simply a repeated stack of them. The fifth and sixth metal layers 64 and 66 are also not shown in FIG. 9 since they are simply a stack of two metal layers.

FIG. 16 shows an example in which each metal layer is integrated with a corresponding conductive plug (i.e., a unitary structure) and all interlevel dielectric layers not shown in the perspective view of the first bonding pad of FIG. 5. Referring to FIG. 16, the first dummy pattern 42 penetrates the first metal layer 40. A first interlevel dielectric layer 44 is present on the first metal layer 40. A first via hole h1 exposing the first metal layer 40 is formed in the first interlevel dielectric layer 44. The first via hole h1 is divided into upper and lower portions and has a T-shape so the diameter of the upper portion is greater than that of the lower portion. The first via hole h1 is filled with a metal layer. While one portion of the metal layer filled in the lower portion of the first via hole h1 corresponds to the first conductive plug CP1, the other portion filled in the upper portion corresponds to the second metal layer 46. A region of the first interlevel dielectric layer 44 between the first via holes h1 is inverted T-shaped so an upper portion of the region is narrower than a lower portion. The upper portion of the region in the first interlevel dielectric layer 44 corresponds to the second dummy pattern 48.

A second interlevel dielectric layer 50 covering the metal layer filled in the first via hole h1 overlies the first interlevel dielectric layer 44. A second via hole h2 directly overlying the first via hole h1 is formed in the second interlevel dielectric layer 50 and exposes the metal layer filled in the first via hole h1. The second via hole h2 has the same shape as the first via hole h1, and a metal layer filled in the second via hole h2 may be the same as that filled in the first via hole h1.

A third interlevel dielectric layer 56 is formed on the second interlevel dielectric layer 50 and covers the metal layer filled in the second via hole h2. A third via hole h3 directly overlying the second via hole h2 is T-shaped like the first via hole h1. A metal layer filled in the third via hole h3 may be the same as the metal layer filled in the first via hole h1. While upper and lower portions of the metal layer filled in the second via hole h2 correspond to the third metal layer 52 and the second conductive plug CP2, respectively, those of the metal layer filled in the third via hole h3 correspond to the fourth metal layer 60 and the third conductive plug CP3, respectively. An upper portion of the second interlevel dielectric layer 50 between the second via holes h2 corresponds to the third dummy pattern 54 distributed over the third metal layer 52. Similarly, an upper portion of the third interlevel dielectric layer 56 between the third via holes h3 corresponds to the fourth dummy pattern 58 distributed over the fourth metal layer 60.

A fourth interlevel dielectric layer 62 is formed on the third interlevel dielectric layer 56 and covers the metal layer filled in the third via hole h3. A fourth via hole h4 is formed in a fourth interlevel dielectric layer 62 and exposes a portion of the third interlevel dielectric layer 56 and the metal layer filled in the third via hole h3. The fourth via hole h4 is filled with the fifth metal layer 64. The fifth metal layer 64 may be the same as that filled in the first via hole h1. The sixth metal layer 66 is formed on the fourth interlevel dielectric layer 62 and covers the fifth metal layer 64 filled in the fourth via hole h4.

FIG. 17 is a cross-sectional view of the second bonding pad taken along line 17-17′ of FIG. 13 showing the second bonding pad, assuming that the third through sixth metal layers 52, 60, 64, and 66 and the second and third conductive plugs CP2′ and CP3′ having second patterns overlie the second metal layer 46 shown in FIG. 13. Like FIG. 16, FIG. 17 shows an example in which each metal layer is integrated with a corresponding conductive plug and all interlevel dielectric layers not shown in the perspective view of the second bonding pad of FIG. 6.

Referring to FIG. 17, a first interlevel dielectric layer 44 is formed on the first metal layer 40. A first via hole h11 exposing the first metal layer 40 is formed in the first interlevel dielectric layer 44 and subsequently filled with the second metal layer 46. The first via hole h11 is divided into a larger-diameter upper region and a smaller-diameter lower region. The lower region of the first via hole h11 is separated into two parts with an equal diameter. While one portion of the second metal layer 46 filled in the lower region of the first via hole h11 corresponds to the first conductive plug CP1′ having the second pattern, the other portion filled in the upper region corresponds to the second metal layer 46. An upper portion of a region of the first interlevel dielectric layer 44 between the first via holes h11 corresponds to the second dummy pattern 48 embedded in the second metal layer 46.

A second interlevel dielectric layer 50 covering the second metal layer 46 filled in the first via hole h11 overlies the first interlevel dielectric layer 44. A second via hole h22 having the same shape as the first via hole h11 is formed in the second interlevel dielectric layer 50 and subsequently filled with the third metal layer 52. A portion of the third metal layer 52 filled in a lower region of the second via hole h22 corresponds to the second conductive plug CP2′ having the second pattern. A portion of the second interlevel dielectric layer 50 between upper regions of the second via holes h22 corresponds to the third dummy pattern 54 distributed in the third metal layer 52.

A third interlevel dielectric layer 56 is formed on the second interlevel dielectric layer 50 and covers the third metal layer 52 filled in the second via hole h22. A third via hole h33 exposing the third metal layer 52 is formed in the third interlevel dielectric layer 56 and subsequently filled with the fourth metal layer 60. The third via hole h33 has the same shape as the first via hole h11, and the fourth metal layer 60 may be the same as the first metal layer 40. A portion of the fourth metal layer 60 filled in a lower region of the third via hole h33 corresponds to the third conductive plug CP3′ having the second pattern. An upper portion of the third interlevel dielectric layer 56 between the third via holes h33 corresponds to the fourth dummy pattern 58.

A fourth interlevel dielectric layer 62 is formed on the third interlevel dielectric layer 56 and covers the fourth metal layer 60. A fourth via hole h4 is formed in a fourth interlevel dielectric layer 62 and subsequently filled with the fifth metal layer 64. The diameter of the fourth via hole h4 is much greater than those of the first through third via holes h11-h33, thus exposing a majority portion of the fourth metal layer 60 and the upper portions 58 of the third interlevel dielectric layer 54 between the fourth metal layer 60 filled in the third via hole h33. The fifth metal layer 64 may be the same as that the first metal layer 40. The sixth metal layer 66 is formed on the fourth interlevel dielectric layer 62 and covers the fifth metal layer 64.

While via holes formed in multiple interlevel dielectric layers have been arranged vertically in the illustrative embodiments described above, they may be arranged in a staggered fashion. In other words, the via holes may be offset from one another in a vertical direction.

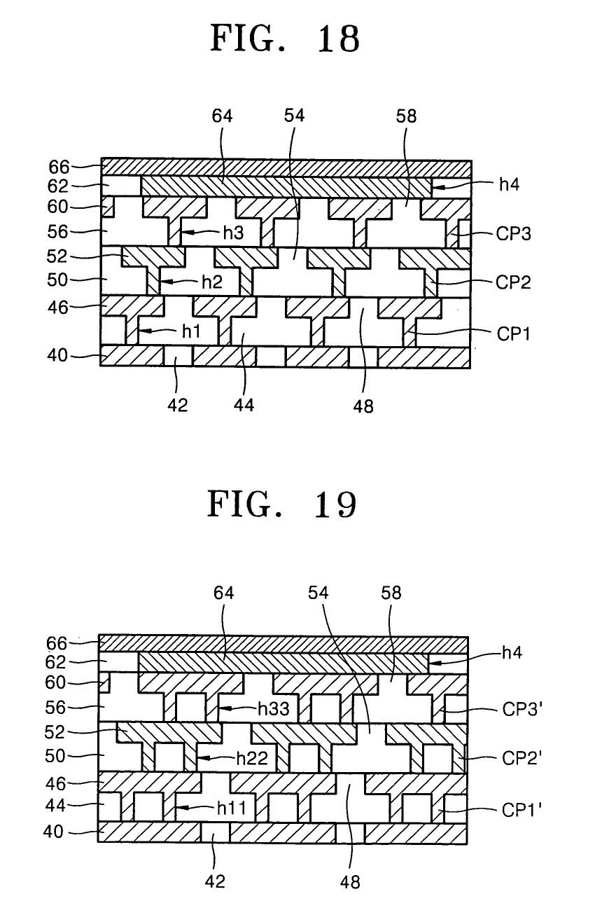

FIG. 18 shows an example in which the first through third via holes h1-h3 formed in the first through third interlevel dielectric layers 44, 50, and 56 are displaced slightly to the right from the counterparts in the first bonding pad shown in FIG. 16. Furthermore, the first through third via holes h1-h3 are arranged obliquely. They may be arranged in different ways, e.g., in a zigzag pattern or offset from one another.

FIG. 19 shows an example in which the first through third via holes h11-h33 formed in the first through third interlevel dielectric layers 44, 50, and 56 are displaced slightly to the right from the counterparts in the second bonding pad shown in FIG. 17. In this case, the first through third via holes h11-h33 may also be arranged in a zigzag pattern or offset from one another.

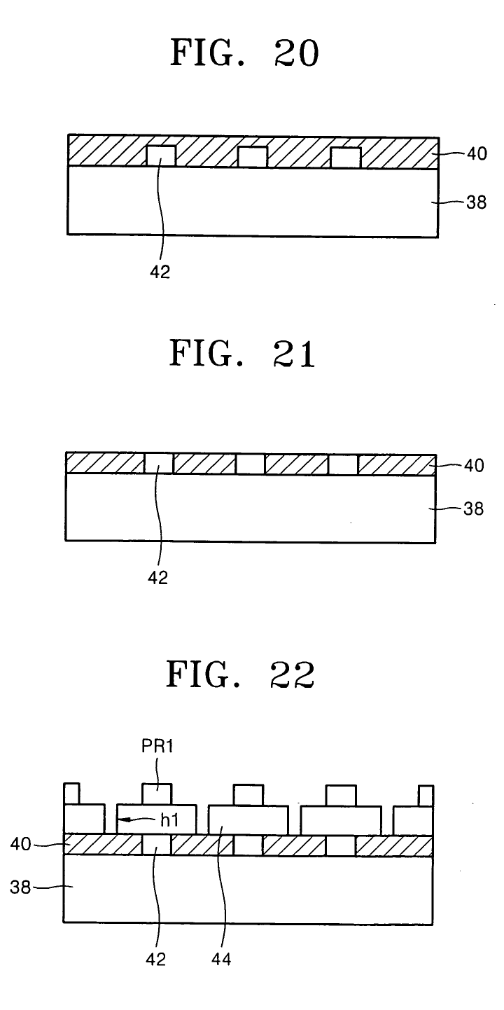

FIGS. 20-28 are cross-sectional views showing methods of forming a bonding pad of FIG. 5 according to some embodiments of the present invention. Referring to FIG. 20, a first dummy pattern 42 having a first shape is formed on an underlying layer 38 (pad conductive layer) connected to a semiconductor device and is separated from each other by a predetermined distance. A first metal layer 40 covering the first dummy pattern 42 having the first shape is formed on the pad conductive layer 38 and CMP is then performed to planarize the surface of the first metal layer 40. The first metal layer 40 may be made of copper, and the CMP process continues until the first dummy pattern 42 having the first shape is exposed as shown in FIG. 21. Thereby, the first dummy pattern 42 having the first shape is distributed over the first metal layer 40. The first dummy pattern 42 may have other various shapes.

Referring to FIG. 22, after CMP, a first interlevel dielectric layer 44 covering the first dummy pattern 42 having the first shape is formed on the first metal layer 40, and then a first via hole h1 is formed in the first interlevel dielectric layer 44. Since a second metal layer is filled in a portion of the interlevel dielectric layer 44 removed, the first interlevel dielectric layer 44 is formed to an adequate thickness. The first interlevel dielectric layer 44 may be made of a low-dielectric-constant (k) material. For example, it can be made of a dielectric material having a dielectric constant k lower than k of silicon dioxide (SiO₂). A first photoresist pattern PR1 is formed on the first interlevel dielectric layer as a mask exposing the first via hole h1 and a surrounding portion. Using the first photoresist pattern PR1 as an etch mask, a part of the exposed portion of the first interlevel dielectric layer 44 is etched, followed by removal of the first photoresist pattern PR1.

Referring to FIG. 23, after the etching, a diameter of an upper region of the first via hole h1 is greater than that of a lower region. Thus, the diameter of an upper portion of the first interlevel dielectric layer 44 between the upper regions of the first via hole h1 is less than that of a lower portion thereof. A second metal layer 46 filling the first via hole h1 is formed on the first interlevel dielectric layer 44 and the surface of the second metal layer 46 is then planarized. Since the diameter of the lower region of the first via hole h1 is significantly less than that of the upper region, one portion of the second metal layer 46 filling the lower region of the first via hole h1 substantially acts as a first conductive plug CP1 that connects the other portion filling the upper region with the first metal layer 40. The second metal layer 46 may be made of copper or other materials. The surface of the second metal layer 46 thus formed is then subjected to CMP until the upper portion of the first interlevel dielectric layer 44 is exposed. Since the upper portion of the first interlevel dielectric layer 44 is formed between the second metal layer 46, pattern density of an object to be polished increases compared to when only the second metal layer 46 is formed, so that almost no CMP-produced dishing occurs. The upper portion of the first interlevel dielectric layer 44 exposed by the CMP is used as a second dummy pattern 48 between the second metal layer 46.

Referring to FIG. 24, a second interlevel dielectric layer 50 is formed on the second metal layer 46 filled in the first via hole h1 and the upper portion 48 of the first interlevel dielectric layer 44 exposed by the CMP. The second interlevel dielectric layer 50 is formed from the same dielectric material as the first interlevel dielectric layer 44. A second via hole h2 exposing the second metal layer 46 is formed in the second interlevel dielectric layer 50. The second via hole h2 may be located vertically on the first via hole h1. Also, the second via hole h2 may be located on the second metal layer 46 around the first via hole h1 as shown in FIG. 29.

A second photoresist pattern PR2 exposing the second via hole h2 and a surrounding portion is formed on the second interlevel dielectric layer 50. Subsequently, like in the above etching of the first interlevel dielectric layer 44, an exposed portion A of the second interlevel dielectric layer 50 is etched using the second photoresist pattern PR2 as an etch mask, and the second photoresist pattern PR2 is then removed, thereby forming a second via hole h2 having the same shape as the first via hole h1 formed in the first interlevel dielectric layer 44.

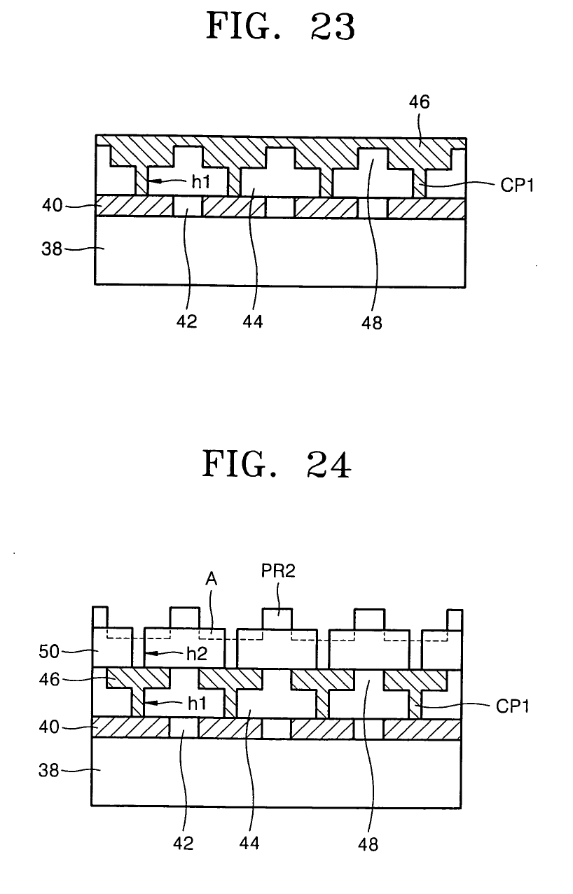

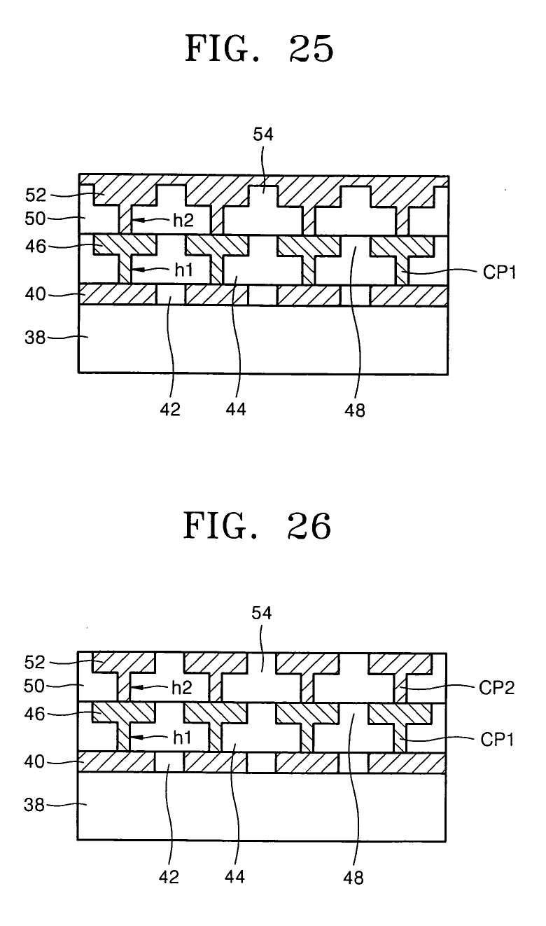

Referring to FIG. 25, a third metal layer 52 filling the second via hole h2 is formed on the second interlevel dielectric layer 50 and the surface of the third metal layer 52 is subjected to planarization. The third metal layer 52 may be made of the same material as the first metal layer 40. Subsequently, the planarized surface of the third metal layer 52 can be polished using CMP until the second interlevel dielectric layer 50 is exposed. For the same reason as in polishing the second metal layer 46, almost no dishing effect occurs during the CMP of the third metal layer 52.

FIG. 26 shows a resulting structure obtained after the CMP of the third metal layer 52. Referring to FIG. 26, one portion of the third metal layer 52 filled in a lower region of the second via hole h2 is used as a second conductive plug CP2 connecting the other portion filled in an upper region with the second metal layer 46.

Referring to FIG, 27, a third interlevel dielectric layer 56 is formed on the resulting structure of FIG. 26. Then, a third via hole h3 is formed in the third interlevel dielectric layer 56 so that the diameter of an upper region is different from that of a lower region. The third interlevel dielectric layer 56 may be made of the same material as the first interlevel dielectric layer 44, and the third via hole h3 may be formed in the same way as the first or second via hole h1 or h2. A fourth metal layer 60 filling the third via hole h3 is formed on the third interlevel dielectric layer 56, and the entire surface of the fourth metal layer 60 is polished to remove the fourth metal layer 60 around the third via hole h3. The polishing may be performed using the same polishing technique as for the second or third metal layer 46 or 52.

The fourth metal layer 60 filled in the lower region of the third via hole h3 serves as a third conductive plug CP3 that connects the fourth metal layer 60 filled in the upper region of the third via hole h3 with the third metal layer 52. After polishing of the fourth metal layer 60, the fourth interlevel dielectric layer 62 is formed on the third interlevel dielectric layer 56 to cover the fourth metal layer 60 and an upper portion of the third interlevel dielectric layer 56 between the fourth metal layer 60. The upper portion of the third interlevel dielectric layer 56 is used as a fourth dummy pattern 58. The fourth interlevel dielectric layer 62 may be made of the same material as the first interlevel dielectric layer 44. A fourth via hole h4 is then formed in the fourth interlevel dielectric layer 62 so that its diameter is significantly greater than the maximum diameters of the first through third via holes h1-h3. The fourth metal layer 60 and the upper portions 58 of the third interlevel dielectric layer 56 are exposed through the fourth via hole h4.

Continuously, a fifth metal layer 64 filling the fourth via hole h4 is formed on the fourth interlevel dielectric layer 62 and the surface of the fifth metal layer 64 is then subjected to planarization. The fifth metal layer 64 may be made of the same material as the first metal layer 40. After the planarization, the surface of the fifth metal layer 64 is polished until the fourth interlevel dielectric layer 62 is exposed, thus removing the fifth metal layer 64 formed on the fourth interlevel dielectric layer 62 around the fourth via hole h4. A sixth metal layer 66 being in contact with the entire surface of the fifth metal layer 64 is formed on the fourth interlevel dielectric layer 62. The sixth metal layer 66 may be made of the same material as the first metal layer 40.

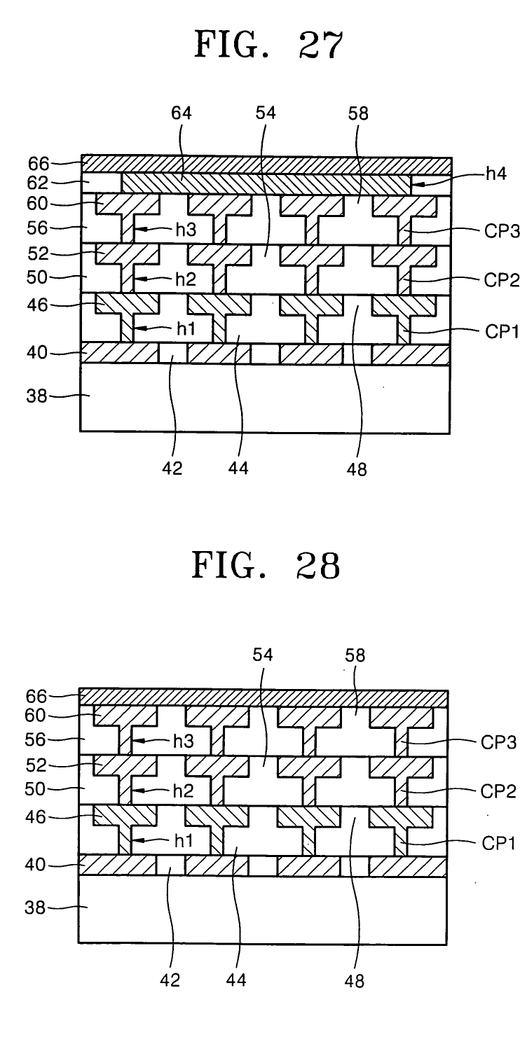

Meanwhile, as shown in FIG. 28, a sixth layer 66 can directly overlie the a third interlevel dielectric layer 56 and the fourth metal layer 60 without interposed fifth metal layer 64 used as a wide pad layer. Although not shown in FIG. 27, the fourth interlevel dielectric layer 62 and the fifth metal layer 64 may be formed in the same pattern as the underlying interlevel dielectric layer and metal layer, for example, the third interlevel dielectric layer 56 and the fourth metal layer 60.

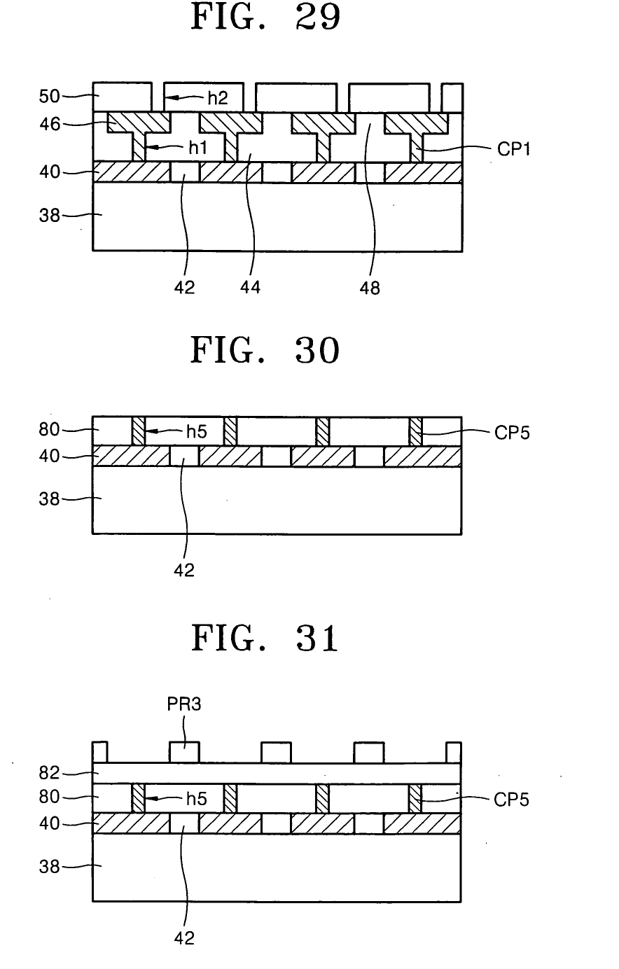

Referring to FIG. 30, a first dummy pattern 42 overlies the pad conductive layer 38, and then a first metal layer 40 is formed between the first dummy pattern 42 in the same way as described in the first embodiment. A fifth interlevel dielectric layer 80 is formed on the first metal layer 40 and the first dummy pattern 42. The fifth interlevel dielectric layer 80 can be made of a low-k material where k is lower than k of silicon dioxide (SiO₂). In this case, the fifth interlevel dielectric layer 80 may be formed thinner than the first through third interlevel dielectric layers (44, 50, and 56 of FIG. 27) in the first embodiment. A fifth via hole h5 exposing the first metal layer 40 is formed in the fifth interlevel dielectric layer 80, followed by the formation of an eleventh conductive plug CP5 in the fifth via hole h5. The eleventh conductive plug CP5 may be made of a copper.

Referring to FIG. 31, a sixth interlevel dielectric layer 82 covering the eleventh conductive plug CP5 is formed on the fifth interlevel dielectric layer 80. The sixth interlevel dielectric layer 82 may be made of the same material as the fifth interlevel dielectric layer 80. The fifth and sixth interlevel dielectric layer 80 and 82 function as upper and lower portions of the first interlevel dielectric layer 44 in the first embodiment, respectively. Then, a third photoresist pattern PR3 is formed on the sixth interlevel dielectric layer 82 and located directly above the first dummy pattern 42. Using the third photoresist pattern PR3 as an etch mask, an exposed portion of the sixth interlevel dielectric layer 82 is etched until the eleventh conductive plug CP5 is exposed, followed by removal of the third photoresist pattern PR3.

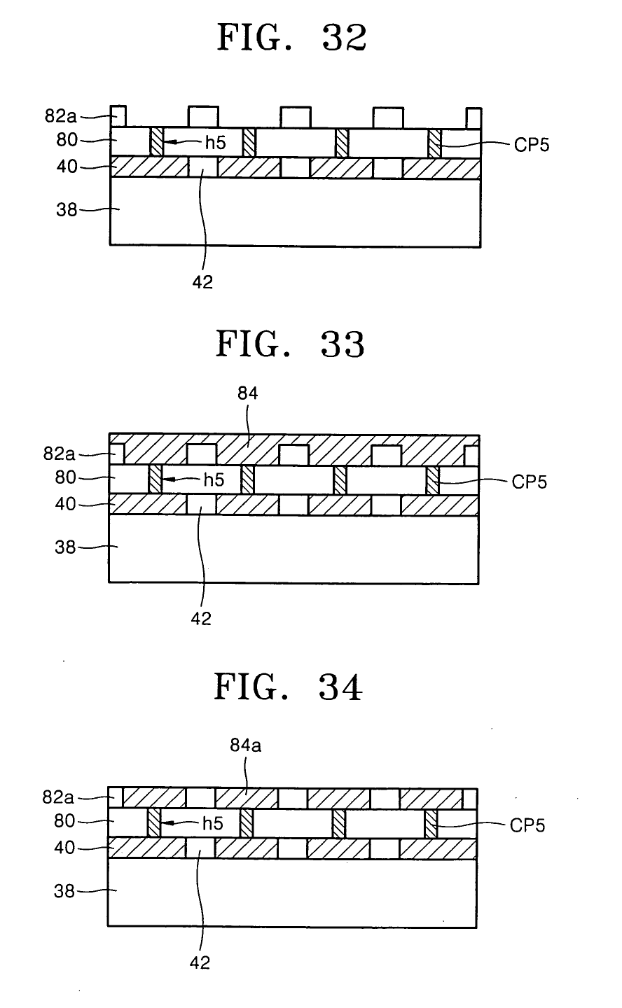

Referring to FIG. 32, the above etching is performed to form a sixth interlevel dielectric pattern 82a only at positions on the fifth interlevel dielectric layer 80 corresponding to the first dummy pattern 42 and expose the eleventh conductive plug CP5 and the fifth interlevel dielectric layer 80 between the eleventh conductive plug CP5 and the sixth interlevel dielectric pattern 82a. The sixth interlevel dielectric pattern 82a is used as a fifth dummy pattern.

Referring to FIG. 33, a seventh metal layer 84 covering the eleventh conductive plug CP5 and the sixth interlevel dielectric pattern 82a is formed on the fifth interlevel dielectric layer 80, and the surface of the seventh metal layer 84 is planarized. The seventh metal layer 84 may be made of the same material as the first metal layer 40. Subsequently, the surface of the seventh metal layer 84 may be polished with a CMP technique until the sixth interlevel dielectric pattern 82a is exposed. In this case, almost no CMP-produced dishing effect occurs for the same reason as in polishing the second metal layer (46 of FIG. 23).

Referring to FIG. 34, after CMP of the seventh metal layer 84, a seventh metal pattern 84a being in contact with the eleventh conductive plug CP5 is formed on the fifth interlevel dielectric layer 80 between the sixth interlevel dielectric patterns 82a. The seventh metal pattern 84a and the eleventh conductive plug CP5 are the same as the second metal layer 46 in the first embodiment and the first conductive plug CP1 that is the portion of the second metal layer 46 filled with the lower region of first via hole h1. For a subsequent process, the steps shown in FIGS. 31-33 are repeated to sequentially form an interlevel dielectric layer, on which a metal layer and a conductive plug corresponding to the third and fourth metal layers 52 and 60 in the first embodiment, respectively, is subsequently formed. Then, the fifth and sixth metal layers 64 and 66 in the first embodiment may be sequentially formed or only the sixth metal layer 66 is formed. In the former case, the fifth metal layer 64 may be formed by a combination of the eleventh conductive plug CP5 and the seventh metal pattern 84a instead of a wide pad layer. It will be understood by those skilled in the art that the fifth metal layer 64 may be partitioned into two parts, e.g. two or more slits.

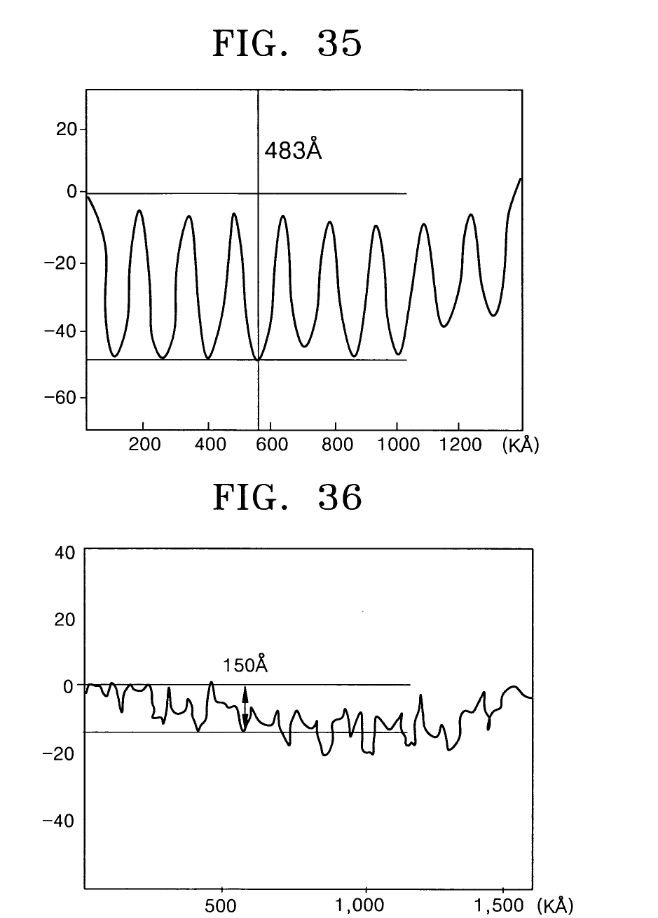

FIGS. 35 and 36 shows the results of measurements of dishing effects on a conventional bonding pad and the bonding pad according to an embodiment of the present invention described above. Referring to FIGS. 35 and 36, a step height between the center and the edge of the conventional bonding pad is about 483 Å while that of the bonding pad according to the present invention is about 150 Å that is significantly less than that of the conventional bonding pad.

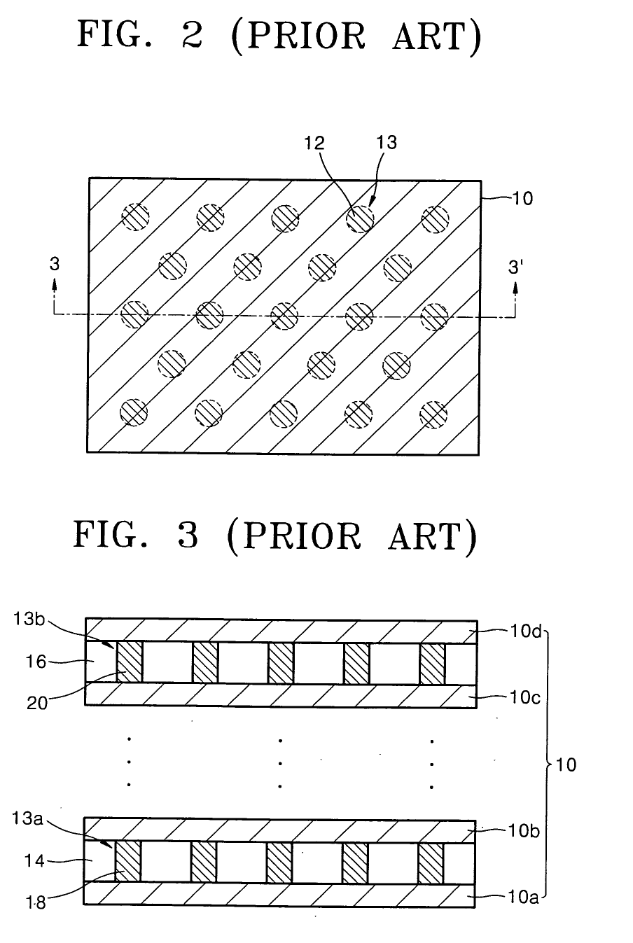

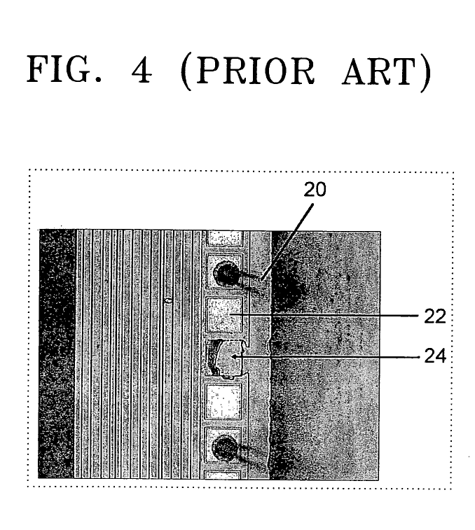

An analysis of the mechanical strength of the conventional bonding pad of FIG. 2 with conductive plug elements arranged in an array was compared to a bonding pad (i.e., a first bonding pad) analogous to that illustrated in of FIG. 5 according to the present invention. For the first bonding pad, no bonding pad was “ripped off” when a pitch between unit meshes M1 is 70 μm, 60 μm, and 55 μm, respectively. In comparison 3 of 120 conventional bonding pads with a pitch of 50 μm were “ripped off”.

Conversely, for the conventional bonding pad, no bonding pad was “ripped off” when a pitch between conductive plug elements is 70 μm and 60 μm, respectively, whereas 3 of 150 conventional bonding pads and 15 of 150 conventional bonding pads were “ripped off” when a pitch is 55 μm and 50 μm, respectively.

As described above, the bonding pad of the present invention provides high pattern density due to the presence of dummy patterns distributed over a stack of multiple metal layers, thereby allowing a reduction in a dishing effect in CMP when compared to the conventional bonding pad. Furthermore, a bonding pad according to embodiments of the invention includes a mesh-shaped, doughnut-shaped or a combination of mesh-shaped and doughnut-shaped conductive plugs connecting a stack of multiple metal layers with each other, thereby allowing increased mechanical strength during a bonding process. In addition, the bonding pad can include a low-k interlevel dielectric layer(s), thereby allowing a reduction in parasitic capacitance.

While this invention has been particularly shown and described with reference to embodiments thereof, the preferred embodiments should be considered in descriptive sense only and not for purposes of limitation. Therefore, the scope of the invention is defined not by the detailed description of the invention but by the appended claims.

1. A bonding pad in a semiconductor device comprising:
a conductive plug pattern on a conductive layer, the conductive layer including a conductive material and a dummy pattern surrounded by the conductive material.

2. The bonding pad according to claim 1 wherein the dummy pattern comprises an insulating material.

3. The bonding pad according to claim 1 wherein the conductive material comprises a first conductive material and wherein the dummy pattern comprises a second conductive material.

4. The bonding pad according to claim 1 wherein the dummy pattern comprises a polygonal shaped element.

5. The bonding pad according to claim 4 wherein the dummy pattern comprises a cross shaped dummy element, a circular shaped dummy element, a rectangular shaped dummy element, a square shaped dummy element, and/or a triangular shaped dummy element.

6. The bonding pad according to claim 1 wherein the conductive plug pattern comprises a conductive element having at least one opening therein opposite the dummy pattern.

7. The bonding pad according to claim 6 wherein the at least one opening is filled with a dielectric material.

8. The bonding pad according to claim 1 wherein the dummy pattern further comprises a plurality of dummy elements surrounded by the conductive material, the conductive plug pattern further comprising a conductive element including an array of openings therein opposite respective ones of the plurality of dummy elements.

9. The bonding pad according to claim 1 wherein the dummy pattern further comprises a plurality of dummy elements surrounded by the conductive material, the conductive plug pattern further comprising a plurality of conductive elements each having an opening therein opposite a respective one of the plurality of dummy elements.

10. The bonding pad according to claim 9 wherein the plurality of conductive elements are connected via conductive interconnects.

11. The bonding pad according to claim 1 wherein the dummy pattern further comprises a plurality of dummy elements surrounded by the conductive material, the conductive plug pattern further comprising a plurality of conductive elements each having an opening therein offset from respective ones of the plurality of dummy elements.

12. The bonding pad according to claim 11 wherein the plurality of conductive elements are connected via conductive interconnects.

13. The bonding pad according to claim 1 wherein the conductive plug pattern comprises a first conductive plug pattern, the conductive layer comprises a first conductive layer including a first conductive material and an embedded first dummy pattern surrounded by the first conductive material, the bonding pad further comprising:
a second conductive layer on the first conductive plug pattern opposite the first conductive layer, the second conductive layer including a second conductive material and an embedded second dummy pattern opposite openings in the first conductive plug pattern and surrounded by the second conductive material.

14. The bonding pad according to claim 13 further comprising:
a second conductive plug pattern on the second conductive layer opposite the first conductive plug pattern, the second conductive plug pattern including openings therein opposite the embedded second dummy pattern.

15. A method of forming a bonding pad in a semiconductor device comprising:
forming a conductive plug pattern on a conductive layer, the conductive layer including a conductive material and a dummy pattern surrounded by the conductive material.

16. The method according to claim 15 wherein forming a conductive plug pattern comprises forming the conductive element having at least one opening therein opposite the dummy pattern.

17. A method of forming a bonding pad in a semiconductor device, comprising:
forming a dummy pattern on an underlying layer;
forming a conductive material covering the dummy pattern on the underlying layer;
removing a portion of the conductive material to expose the dummy pattern to form a conductive layer with the dummy pattern surrounded by the conductive material;
forming an interlevel dielectric layer on the conductive layer to expose a portion of the conductive material therethrough and opposite the dummy pattern; and
forming a conductive plug on the exposed portion of the conductive material to avoid forming the conductive plug on the interlevel dielectric layer opposite the dummy pattern.

18. The method according to claim 17 wherein the conductive material comprises a first conductive material, wherein forming a conductive plug further comprises:
forming a second conductive material on the exposed portion of the first conductive material and on a surface of the interlevel dielectric layer to provide a second conductive layer so that a portion of the second conductive layer and the conductive plug are formed as a unitary structure.

19. The method according to claim 18 wherein the interlevel dielectric layer comprises a first interlevel dielectric layer, the method further comprising:
forming a second interlevel dielectric layer on the second conductive layer to expose a first portion of the second conductive layer and to cover a second portion of the conductive layer opposite the dummy pattern.

20. The method according to claim 17 wherein the dummy pattern comprises a polygonal shaped element.

21. The method according to claim 17 wherein forming a dummy pattern comprises forming a cross shaped dummy element, a circular shaped dummy element, a rectangular shaped element, a square shaped element, and/or a triangular shaped element.

22. A method of manufacturing a bonding pad, comprising:
sequentially stacking a metal layer and an interlevel dielectric layer on an underlying layer at least once;
forming a via hole exposing the metal layer in the interlevel dielectric layer;
filling the via hole with a conductive plug;
forming an intermediate metal layer being in contact with the conductive plug on the interlevel dielectric layer; and
forming a metal layer on the intermediate metal layer,
wherein in sequentially stacking the metal layer and interlevel dielectric layer on the underlying layer, a dummy pattern is formed at a position where the dummy pattern does not contact the conductive plug of at least one of the metal layers.

23. The method of claim 22, wherein in the forming of the intermediate metal layer, the dummy pattern is formed in the intermediate metal layer.

24. The method of claim 22, wherein in sequentially stacking the metal layer and interlevel dielectric layer on the underlying layer, the dummy pattern is formed in all the metal layers stacked on the underlying layer.

25. The method of claim 24, wherein the shape of the dummy pattern varies from layer to layer.

26. The method of claim 22, wherein in sequentially forming a plurality of interlevel dielectric layers between the metal layers on the underlying layer, the via hole formed in each of the plurality of interlevel dielectric layers varies in shape.

27. The method of claim 22, wherein the via hole is mesh-shaped, doughnut-shaped, or designed as a combination of the two shapes.

28. The method of claim 22, wherein the conductive plug and the intermediate metal layer are formed at once.

29. The method of claim 24, wherein the dummy pattern is a part of the immediately underlying interlevel dielectric layer.

30. The method of claim 22, wherein the stacking of a metal layer and an interlevel dielectric layer on an underlying layer at least once comprises:
forming a first dummy pattern on the underlying layer;
forming the metal layer covering the first dummy pattern on the underlying layer; and
polishing the metal layer until the first dummy pattern is exposed.

31. The method of claim 22, wherein the forming of a via hole in the interlevel dielectric layer, the filling of the via hole with a conductive plug, and the forming of the intermediate layer on the interlevel dielectric layer comprises:
forming the via hole exposing the metal layer in the interlevel dielectric layer;
forming a mask exposing the interlevel dielectric layer around the via hole on the interlevel dielectric layer;
removing the exposed portion of the interlevel dielectric layer by a predetermined thickness;
forming the metal layer filling the via hole and the portion of the interlevel dielectric layer removed by the predetermined thickness on the interlevel dielectric layer; and
polishing the metal layer until the interlevel dielectric layer is exposed.

32. The method of claim 22, wherein the interlevel dielectric layer is formed by sequentially stacking upper and lower insulating layers.

33. The method of claim 32, wherein the forming of a via hole in the interlevel dielectric layer, the filling of the via hole with a conductive plug, and the forming of the intermediate layer on the interlevel dielectric layer comprises:
forming the via hole exposing the metal layer in the lower insulating layer;
filling the via hole with a conductive plug;
forming the upper insulating layer covering the conductive plug on the lower insulating layer;
forming a mask on a portion of the upper insulating layer formed around the conductive plug;
removing the upper insulating layer around the mask;
removing the mask; and
filling a position where the upper insulating layer has been removed with the metal layer.

34. The method of claim 22, wherein in sequentially stacking a plurality of interlevel dielectric layer on the underlying layer, the location of a via hole formed in each of the plurality of interlevel dielectric layers varies.

35. The method of claim 22, wherein the dummy pattern is formed by forming holes penetrating the metal layer and then filling the holes.

36. The method of claim 22, wherein the dummy pattern is formed by forming grooves in the metal layer and then filling the grooves.
